(19) United States
(12) Patent Application Publication
(10) Pub. No.: US 2009/0303794 A1
(43) Pub. Date: Dec. 10, 2009

(54) Structure and Method of A Field-Enhanced Charge Trapping-DRAM

(75) Inventor: Chao-I Wu, Zhubei City (TW)

Correspondence Address: MACRONIX;C/O HAYNES BEFFEL & WOLFELD LLP, P. O. BOX 366, HALF MOON BAY, CA, 94019, US

(73) Assignee: Macronix International Co., Ltd., Hsinchu (TW)

(21) Appl. No.: 12/133,237

(22) Filed: Jun. 4, 2008

(51) Int. Cl. G11C 11/34; H01L 29/792; H01L 21/8247

(52) U.S. Cl. 365/185.17; 257/324; 438/287; 257/E29.309; 257/E21.679

(57) ABSTRACT

A field-enhanced (FE) charge trapping-DRAM (TDRAM) device is described which is suitable for DRAM applications, and for additional applications with lower power requirements. In some embodiments, the FE-TDRAM device comprises a charge trapping FinFET structure including an upside-down U-shaped volatile programmable structure and an upside-down U-shaped dielectric structure overlying the volatile programmable structure.

### BACKGROUND OF THE INVENTION

1. Field of the Invention

The invention relates generally to memory devices, and in particular to new dynamic random access memory structures and methods for manufacturing of DRAM devices including such cells.

2. Description of Related Art

Dynamic Random Access Memory (DRAM) is a main working memory in computing devices and operates by storing each bit of data as charge on a separate capacitor on an integrated circuit. The stored charge leaks away from the capacitor over time, requiring a periodic read and refresh of the data. Such refreshing occurs relatively frequently; exemplary figures for DRAM refresh times are 64 or fewer milliseconds, which represents the refresh interval of some number of microseconds per memory row multiplied by the number of rows (such as 4K or 8K rows). This refresh requirement renders DRAM less than ideal for particularly energy sensitive applications, such as very low-power mobile devices.

Although DRAM has high power consumption due to refresh, DRAM is fast. Exemplary DRAM clock speeds of hundreds of MHz correspond to memory cycle times of several nanoseconds. Accordingly, an alternative to DRAM cannot operate so slowly as to render it unacceptable for its intended application.

Therefore, it is desirable to have a volatile memory device that is suitable for DRAM applications at high speed yet with low-power.

### SUMMARY OF THE INVENTION

A field-enhanced (FE) charge trapping-DRAM (TDRAM) device is described suitable for DRAM applications with lower power requirements. In some embodiments, the FE-TDRAM device comprises a charge trapping FinFET structure including an upside-down U-shaped volatile programmable structure and an upside-down U-shaped dielectric structure overlying the volatile programmable structure. The volatile programmable structure overlies a protruding semiconductor, which protrudes from the substrate. The FINET-TDRAM memory accordingly comprises a PONIS (Poly/Oxide/Nitride/Si-substrate) structure in some embodiments.

Various embodiments have no bottom oxide layer under the volatile programmable structure to prevent de-trapping of charges, so that the memory is volatile. Various embodiments of the memory structure feature a relatively low barrier height between the volatile programmable structure (e.g., a silicon nitride) and a silicon substrate, to increase charge movement from the silicon substrate to the volatile programmable structure, thereby decreasing power requirements and increasing operation speed. In some embodiments, the volatile programmable structure and dielectric structure bend around the protruding semiconductor in the FinFET memory, producing an electrical field enhancement which increases operational speed.

Broadly stated, one aspect of the technology is a memory integrated circuit with a protruding semiconductor, a volatile programmable structure, a dielectric structure, a gate structure, and control circuitry.

The protruding semiconductor has a source region, a drain region, and a channel region between the source region and the drain region. The protruding semiconductor has a profile with a width and a height. This profile of the protruding semiconductor extends from a substrate by that height.

The volatile programmable structure has an inner surface and an outer surface. The inner surface of the volatile programmable structure contacts the channel region of the protruding semiconductor along at least part of the width and at least part of the height of the protruding semiconductor. The volatile programmable structure has a profile with a width and a height.

The dielectric structure has an inner surface and an outer surface. The inner surface of the dielectric structure contacts the volatile programmable structure along at least part of the width and at least part of the height of the volatile programmable structure. The dielectric structure has a profile with a width and a height.

The gate structure has an inner surface contacting the dielectric structure along at least part of the width and at least part of the height of the dielectric structure.

The control circuitry applies bias arrangements to the protruding semiconductor and the gate structure.

Advantageously, the FinFET-type of TDRAM structures increase the operational speed of a integrated circuit memory device and reduce the operational voltage for DRAM applications.

The structures and methods of the present invention are disclosed in the detailed description below. This summary does not purport to define the invention. The invention is defined by the claims. These and other embodiments, features, aspects, and advantages of the invention will become better understood with regard to the following detailed description, appended claims and accompanying drawing.

### BRIEF DESCRIPTION OF THE DRAWINGS

FIG. 1 illustrates a cross-sectional view of a FinFET-TDRAM memory structure with a PONIS (Poly/Oxide/Nitride/Si-substrate) structure having a low barrier height (LBH).

FIG. 2 illustrates a perspective view of the FinFET-TDRAM memory with a PONIS structure of FIG. 1.

FIGS. 3A and 3B are energy band diagrams illustrating the low barrier height with a silicon nitride/silicon interface, compared to a silicon oxide/silicon interface.

FIG. 4A shows programming via electron injection of the FinFET-TDRAM memory structure shown in FIG. 1.

FIG. 4B shows the bias arrangement for programming via electron injection of the FinFET-TDRAM memory structure shown in FIG. 4A.

FIG. 5A shows erasing via hole injection of the FinFET-TDRAM memory structure shown in FIG. 1.

FIG. 5B shows the bias arrangement for erasing via hole injection of the FinFET-TDRAM memory structure shown in FIG. 5A.

FIG. 6 illustrates a flow diagram for performing a FinFET-TDRAM refresh operation of the memory structure.

FIG. 7 is a graph of threshold voltage shift vs. program time, contrasting a FinFET-TDRAM memory with a planar TDRAM memory.

FIG. 8 is a graph of threshold voltage shift vs. erase time, contrasting a FinFET-TDRAM memory and a planar TDRAM memory.

FIG. 9 is a simplified block diagram of an integrated circuit with an array of FinFET-TDRAM memories.

### DETAILED DESCRIPTION

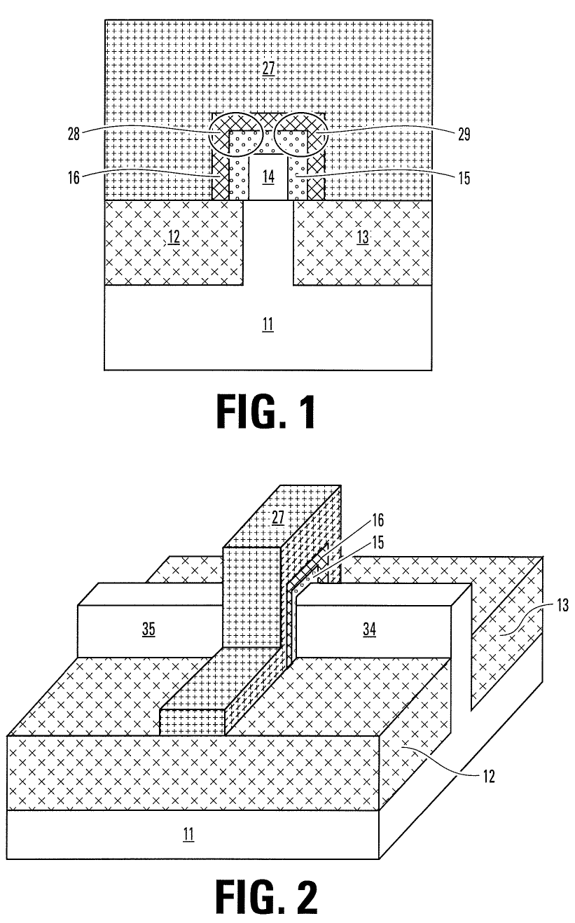

FIG. 1 illustrates a cross-sectional view of a FinFET-TDRAM memory structure with a PONIS (Poly/Oxide/Nitride/Si-substrate) structure. The memory is formed on a semiconductor substrate 11 (such as p-type silicon) with a first isolation oxide region 12 and a second isolation oxide region 13. A protruding semiconductor 14 of the memory extends from the semiconductor substrate 11, and is between the first isolation oxide 12 and the second isolation oxide 13. A volatile programmable structure 15 of the memory has an upside-down U-shape and covers the protruding semiconductor 14. The dielectric structure 16 also has an upside-down U-shape and covers the volatile programmable structure 15. A gate structure 27 covers the dielectric structure 16.

The bending parts of the volatile programmable structure 15 and the dielectric structure 16 form a first corner region 28 and a second corner region 29 in the volatile programmable structure. The first and second corner regions 28, 29 in the volatile programmable structure 15 cause a concentration in the electrical field lines from the gate 27 to the protruding semiconductor 14, peaking at the interface between the volatile programmable structure 15 and the protruding semiconductor 14, thereby enhancing charge movement in those regions of the memory. Thus, operational speed is increased while reducing the operational voltage of the memory at the first and second corner regions 28, 29.

In other embodiments, the protruding semiconductor 14 has the shape of a triangle, another pointed shape, a semicircle, or other rounded shape. In such embodiments, the volatile programmable structure 15 and the dielectric structure 16 bend to follow the shape of the protruding semiconductor 14. Field enhancement occurs so long as the inner surface area of the volatile programmable structure 15 adjacent to the protruding semiconductor 14 is smaller than the outer surface area of the volatile programmable structure 15 adjacent to the dielectric structure 16.

FIG. 2 illustrates a perspective view of the FinFET-TDRAM memory with a PONIS structure of FIG. 1. A source region 34 and a drain region 35 are part of the protruding semiconductor. The U-shaped dielectric structure 16 and volatile programmable structure 15 covers the channel region between the source region 34 and a drain region 35.

In one embodiment, the volatile programmable structure 15 is a charge trapping material such as silicon nitride. In another embodiment, the volatile programmable structure 15 is a silicon-rich nitride. The typical SiN is Si₃N₄. So the ratio of Si to N atoms are 3:4 in normal silicon nitride. For silicon-rich nitride, the definition is simply that Si:N>3:4. A typically ratio may ranges from 3.1:4 to 4:4. Another useful parameter is the optical index of refraction (n), measured at 633 nm with an optical ellipsometer. The index of refraction n=2.0 for standard silicon nitride. A typical range for silicon-rich nitride in our experiments is 2.05 to 2.1.

In one embodiment, the U-shaped dielectric structure 16 is implemented with silicon oxide. In other embodiments, the dielectric 16 is implemented with a high-K material having a dielectric constant higher than that of silicon oxide. The U-shaped volatile programmable structure 15 includes a material such as silicon nitride Si₃N₄, aluminum oxide Al₂O₃, and hafnium oxide Hf₂O₃

In one embodiment, the gate structure 27 comprises n-type polysilicon. In other embodiments, the gate structure 27 comprises a material having a work function greater than the intrinsic work function of n-type silicon, or greater than about 4.1 eV, and preferably greater than about 4.25 eV, including for example greater than about 5 eV. Representative gate materials include p-type poly, TiN, Pt, and other high work function metals and materials. Other materials having a relatively high work function suitable for embodiments of the technology include metals including but not limited to Ru, Ir, Ni, and Co, metal alloys including but not limited to Ru—Ti and Ni-T, metal nitrides, and metal oxides including but not limited to RuO₂. High work function gate materials result in higher injection barriers for electron tunneling than that of the typical n-type polysilicon gate. The injection barrier for n-type polysilicon gates with silicon dioxide as the outer dielectric is around 3.15 eV. Thus, embodiments of the present technology use materials for the gate and for the outer dielectric having an injection barrier higher than about 3.15 eV, such as higher than about 3.4 eV, and preferably higher than about 4 eV. For p-type polysilicon gates with silicon dioxide outer dielectrics, the injection barrier is about 4.25 eV, and the resulting threshold of a converged cell is reduced about 2 volts relative to a cell having an n-type polysilicon gate with a silicon dioxide outer dielectric.

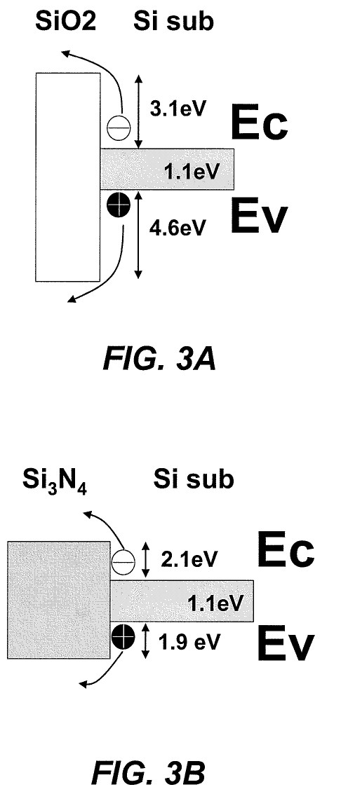

FIGS. 3A and 3B are energy band diagrams illustrating the low barrier height with a silicon nitride/silicon interface, compared to a silicon oxide/silicon interface. FIG. 3A shows hole injection and electron injection from the silicon substrate on the right to the silicon oxide on the left. The silicon substrate has a forbidden gap 1.1 eV wide separating the conduction band Ec and the valence band Ev. The silicon oxide/silicon interface presents a 3.1 eV barrier height to electrons between the conduction band edges of the silicon oxide/silicon interface, and a 4.6 eV barrier height to holes between the valence band edges of the silicon oxide/silicon interface. FIG. 3B shows hole injection and electron injection from the silicon substrate on the right to the silicon nitride on the left. The silicon nitride/silicon interface presents a 2.1 eV barrier height to electrons between the conduction band edges of the silicon nitride/silicon interface, and a 1.9 eV barrier height to holes between the valence band edges of the silicon nitride/silicon interface. Mechanisms for charge movement past such barrier heights involve hot carriers and/or tunneling. Many such current mechanisms have a current magnitude that is a function of the energy gap as an exponent of e, so that even relatively small changes in barrier height have a tremendous effect on charge movement. Such low barrier heights as with the silicon nitride/silicon interface provide faster operational speed at lower operation voltages.

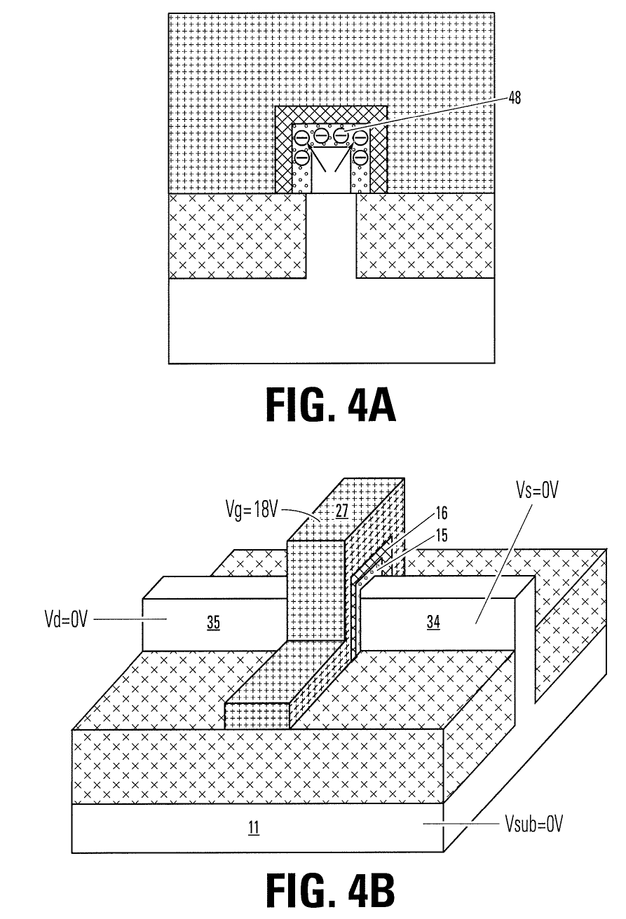

FIG. 4A shows programming via electron injection of the FinFET-TDRAM memory structure shown in FIG. 1. Electrons 48 are shown being injected from the protruding semiconductor into the volatile programmable structure. FIG. 4B shows the bias arrangement for programming via electron injection of the FinFET-TDRAM memory structure shown in FIG. 4A. To program the memory structure 46, a gate voltage Vg of 18 volts is applied to the gate 27, a substrate voltage of 0 volts is applied to the substrate 11, a drain voltage Vd of 0 volts is applied to the drain 35, and a source voltage Vs of 0 volts is applied to the source 34.

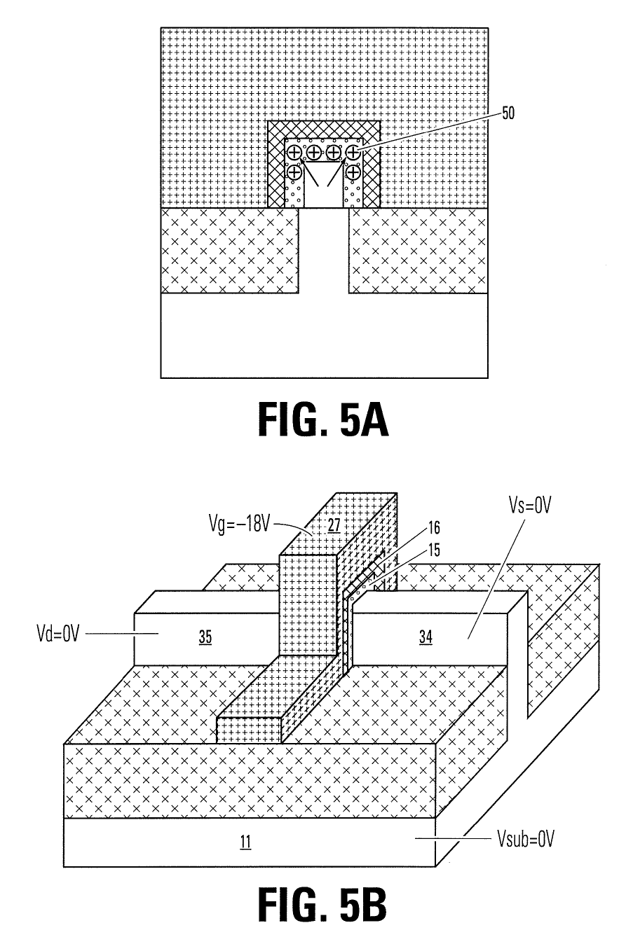

FIG. 5A shows erasing via hole injection of the FinFET-TDRAM memory structure shown in FIG. 1. Holes 50 are shown being injected from the protruding semiconductor into the volatile programmable structure. FIG. 4B shows the bias arrangement for erasing via hole injection of the FinFET-TDRAM memory structure shown in FIG. 5A. To erase the memory structure 46, a gate voltage Vg of −18 volts is applied to the gate 27, a substrate voltage of 0 volts is applied to the substrate 11, a drain voltage Vd of 0 volts is applied to the drain 35, and a source voltage Vs of 0 volts is applied to the source 34.

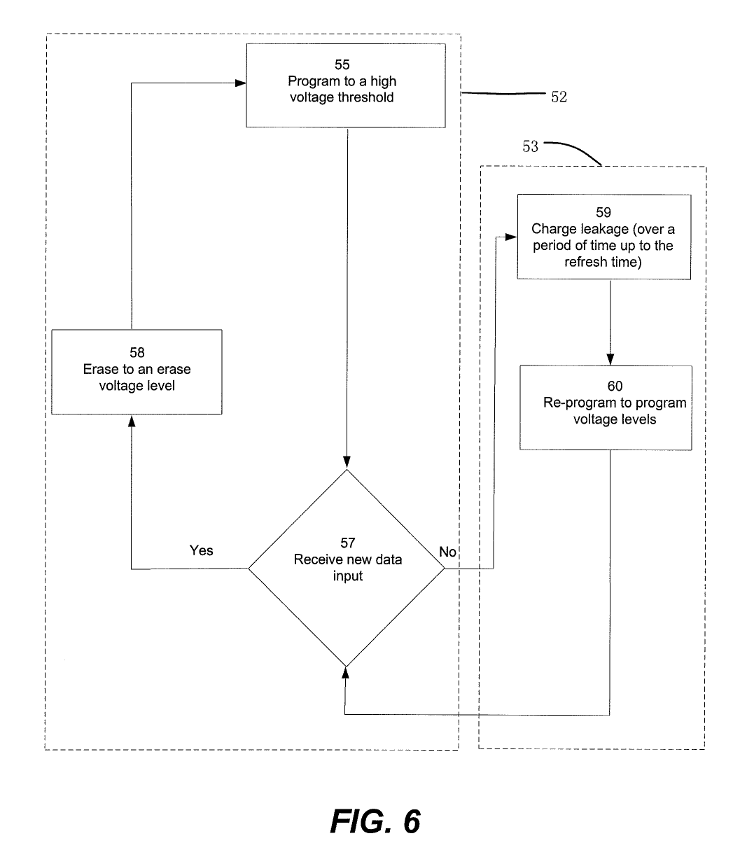

FIG. 6 illustrates a flow diagram for performing a FinFET-TDRAM refresh operation of the memory structure. Regular programming operation is shown by a first group of steps 52, to program new data into the memory. The refresh operation is shown by a second group of steps 53 to refresh the memory by re-programming the original data in the memory. At step 57, it is determined whether the memory structure receives new data input for programming. If new data input exists, at step 58, the memory undergoes an erase operation to erase the memory to an erase voltage (EV) level. At step 55, the memory is programmed to a programmed voltage (PV) level.

However, if the memory structure does not receive new data input, the process proceeds to step 59, during which charge leakage occurs over a period of time up to the refresh time. In one embodiment, the refresh time is at least 1 second, significantly longer than the refresh time of a conventional DRAM which is typically in milliseconds. The FinFET-TDRAM executes a nondestructive read so that it is not necessary to consider a refresh cycle during a normal operation. Accordingly, refresh for a FinFET-TDRAM memory occurs significantly less often than for a conventional DRAM memory. The memory is re-programmed to the PV voltage level at step 60. If the memory was at the EV voltage level, refresh is unnecessary. Because of the nondestructive read, the memory structure is refreshed without erase. After the re-programming, the flow returns to step 57 to determine if there is any new data input.

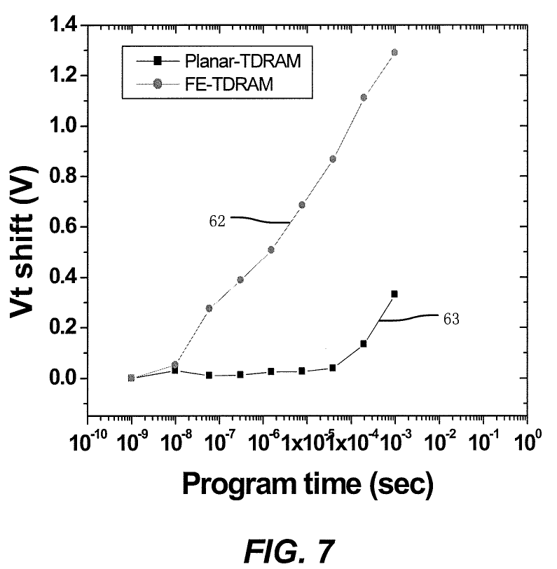

FIG. 7 is a graph of threshold voltage shift vs. program time, contrasting a FinFET-TDRAM memory with a planar-TDRAM memory. The planar-TDRAM memory has flat layers of volatile programmable structure and dielectric structure separating the volatile programmable structure from the gate, so that the volatile programmable structure and the dielectric structure do not bend. The x-axis represents program time and the y-axis represents threshold voltage shift. Curve 62 shows sample program data points for a FinFET-TDRAM. Curve 63 shows sample program data points for a planar-TDRAM. The programming speed for the FinFET-TDRAM is significantly faster than for the planar-TDRAM. For example, to achieve a threshold voltage shift of a little over 0.3 V, the program time for a FinFET-TDRAM is about 100 nanoseconds, and the program time for a planar-TDRAM is about 1 millisecond, so that the programming speed for the FinFET-DRAM is about 10,000 times faster than the planar-DRAM.

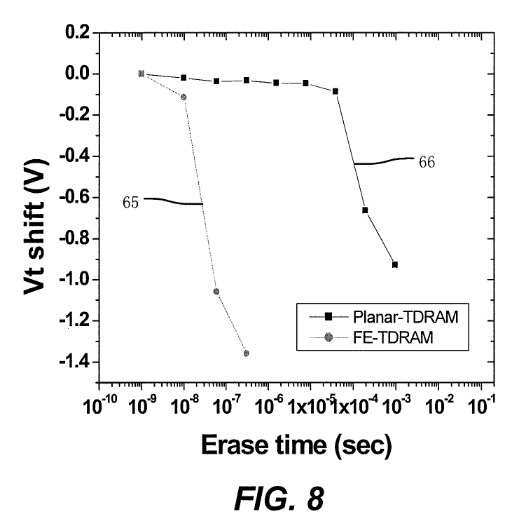

FIG. 8 is a graph of threshold voltage shift vs. erase time, contrasting a FinFET-TDRAM memory and a planar TDRAM memory. The x-axis represents erase time in seconds and the y-axis represents threshold voltage shift. Curve 65 shows sample erase data points for a FinFET-TDRAM. Curve 66 shows sample erase data points for a planar-TDRAM. The erasing speed for the FinFET-TDRAM is significantly faster than for the planar-TDRAM. For example, to achieve a threshold voltage shift of about −0.65 V, the erase time for a FinFET-TDRAM is about 25 nanoseconds, and the program time for a planar-TDRAM is about 200 microseconds, so that the programming speed for the FinFET-DRAM is about 8,000 times faster than the planar-DRAM.

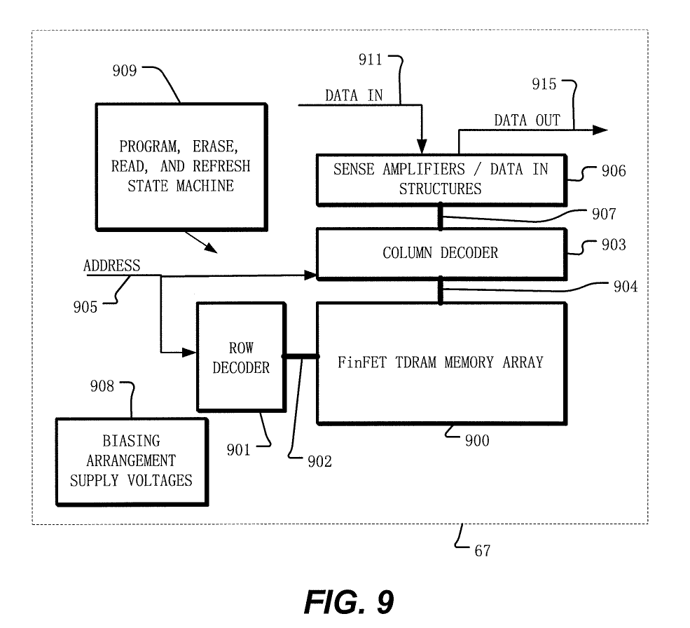

FIG. 9 is a simplified block diagram of an integrated circuit with an array of FinFET-TDRAM memories. The integrated circuit 67 includes a memory array 900 implemented using nonvolatile memories as described herein on a semiconductor substrate, including a FinFET-TDRAM array of memories. The memories of array 900 may be interconnected in parallel (e.g., NOR), in series (e.g., NAND), or in a virtual ground array. A row decoder 901 is coupled to a plurality of word lines 902 arranged along rows in the memory array 900. A column decoder 903 is coupled to a plurality of bit lines 904 arranged along columns in the memory array 900. Addresses are supplied on bus 905 to column decoder 903 and row decoder 901. Sense amplifiers and data-in structures in block 906 are coupled to the column decoder 903 via data bus 907. Data is supplied via the data-in line 911 from input/output ports on the integrated circuit 67, or from other data sources internal or external to the integrated circuit 67, to the data-in structures in block 906. Data is supplied via the data-out line 915 from the sense amplifiers in block 906 to input/output ports on the integrated circuit 67, or to other data destinations internal or external to the integrated circuit 67. A state machine 909 controls the application of bias arrangement supply voltages 908, such as for the program, erase, read, and refresh operations.

The array may be combined on the integrated circuit with other modules, such as processors, other memory arrays, programmable logic, dedicated logic etc.

While the present invention is disclosed by reference to the preferred embodiments and examples detailed above, it is to be understood that these examples are intended in an illustrative rather than a limiting sense. It is contemplated that modifications and combinations will readily occur to those skilled in the art, which modifications and combinations will be within the spirit of the invention and the scope of the following claims.

1. A memory integrated circuit, comprising:
a protruding semiconductor having a source region, a drain region, and a channel region between the source region and the drain region, the protruding semiconductor having a profile with a width and a height, the profile of the protruding semiconductor protruding from a substrate by the height;
a volatile programmable structure covering the protruding semiconductor, the volatile programmable structure having an inner surface and an outer surface, the inner surface of the volatile programmable structure contacting the channel region of the protruding semiconductor along at least part of the width and at least part of the height of the protruding semiconductor, the volatile programmable structure having a profile with a width and a height;
a dielectric structure having an inner surface and an outer surface, the inner surface of the dielectric structure contacting the volatile programmable structure along at least part of the width and at least part of the height of the volatile programmable structure, the dielectric structure having a profile with a width and a height;
a gate structure having an inner surface contacting the dielectric structure along at least part of the width and at least part of the height of the dielectric structure;
control circuitry applying bias arrangements to the protruding semiconductor and the gate structure.

2. The integrated circuit of claim 1, wherein the volatile programmable structure and the dielectric structure each have a profile including an upside-down U-shape.

3. The integrated circuit of claim 1, wherein the volatile programmable structure and the dielectric structure bend around the protruding semiconductor, such that the volatile programmable structure and the dielectric structure form at least one corner.

4. The integrated circuit of claim 1, wherein the volatile programmable structure stores a volatile state of the integrated circuit.

5. The integrated circuit of claim 1, wherein the volatile programmable structure and the dielectric structure bend around the protruding semiconductor, such that the volatile programmable structure and the dielectric structure form at least one corner, and the volatile programmable structure stores a volatile state of the integrated circuit at said at least one corner.

6. The integrated circuit of claim 1, wherein the volatile programmable structure has a program time of less than about 100 nanoseconds to cause a voltage shift magnitude of more than about 0.3 V.

7. The integrated circuit of claim 1, wherein the volatile programmable structure has an erase time of less than about 30 nanoseconds to cause a voltage shift magnitude of more than about 0.6 V.

8. The integrated circuit of claim 1, wherein the volatile programmable structure has an erase time of less than about 60 nanoseconds to cause a voltage shift magnitude of more than about 1.0 V.

9. The integrated circuit of claim 1, wherein the volatile programmable structure has a barrier height less than about 3.1 eV against electrons from the protruding semiconductor.

10. The integrated circuit of claim 1, wherein the volatile programmable structure has a barrier height less than about 4.6 eV against holes from the protruding semiconductor.

11. The integrated circuit of claim 1, wherein the protruding semiconductor includes silicon and the volatile programmable structure includes silicon nitride.

12. The integrated circuit of claim 1, wherein the volatile programmable structure comprises at least one of Si₃N₄, Al₂O₃ and Hf₂O₃.

13. The integrated circuit of claim 1, wherein the volatile programmable structure includes a material having a dielectric constant that is greater than about 4.5.

14. The integrated circuit of claim 1, wherein the dielectric structure includes a material having a dielectric constant that is greater than a dielectric constant for silicon dioxide.

15. The integrated circuit of claim 1, wherein the gate structure top comprises polysilicon.

16. The integrated circuit of claim 1, wherein the gate structure top comprises a material having a work function greater than about 4.25 eV.

17. The integrated circuit of claim 1, wherein the volatile programmable structure stores a volatile state of the integrated circuit, with a refresh time of at least 1 second.

18. A memory integrated circuit, comprising:
an array of memories, each of the memories comprising:
a protruding semiconductor having a source region, a drain region and a channel region between the source region and the drain region, the protruding semiconductor having a profile with a width and a height, the profile of the protruding semiconductor protruding from a substrate by the height;
a volatile programmable structure covering the protruding semiconductor, the volatile programmable structure having an inner surface and an outer surface, the inner surface of the volatile programmable structure contacting the channel region of the protruding semiconductor along at least part of the width and at least part of the height of the protruding semiconductor, the volatile programmable structure having a profile with a width and a height;
a dielectric structure having an inner surface and an outer surface, the inner surface of the dielectric structure contacting the volatile programmable structure along at least part of the width and at least part of the height of the volatile programmable structure, the dielectric structure having a profile with a width and a height;
a gate structure having an inner surface contacting the dielectric structure along at least part of the width and at least part of the height of the dielectric structure; and
control circuitry applying bias arrangements to the array of memories.

19. The integrated circuit of claim 18, wherein the array is a NAND array.

20. A method of manufacturing a memory integrated circuit, comprising:
providing a protruding semiconductor having a source region, a drain region, and a channel region between the source region and the drain region, the protruding semiconductor having a profile with a width and a height, the profile of the protruding semiconductor protruding from a substrate by the height;
providing a volatile programmable structure covering the protruding semiconductor, the volatile programmable structure having an inner surface and an outer surface, the inner surface of the volatile programmable structure contacting the channel region of the protruding semiconductor along at least part of the width and at least part of the height of the protruding semiconductor, the volatile programmable structure having a profile with a width and a height;
providing a dielectric structure having an inner surface and an outer surface, the inner surface of the dielectric structure contacting the volatile programmable structure along at least part of the width and at least part of the height of the volatile programmable structure, the dielectric structure having a profile with a width and a height;
providing a gate structure having an inner surface contacting the dielectric structure along at least part of the width and at least part of the height of the dielectric structure; and
providing control circuitry applying bias arrangements to the protruding semiconductor and the gate structure.
